(19) United States
(12) Patent Application Publication
(10) Pub. No.: US 2026/0058101 A1
(43) Pub. Date: Feb. 26, 2026

(54) RESONANT MULTI-REACTOR REMOTE PLASMA SOURCE

(71) Applicant: Applied Materials, Inc., Santa Clara, CA (US)

(72) Inventors: Yuhui ZHANG, Santa Clara, CA (US); Yifan HE, Santa Clara, CA (US); Anil Kumar KALAL, Bengaluru (IN); Yang YANG, San Diego, CA (US); Kartik RAMASWAMY, San Jose, CA (US); Farhad K. MOGHADAM, Saratoga, CA (US); Vishwas BASAVARAJAIAH SOMASHEKAR, Bangalore (IN); Yue GUO, Redwood City, CA (US)

(21) Appl. No.: 18/810,648

(22) Filed: Aug. 21, 2024

(51) Int. Cl. H01J 37/32

(52) U.S. Cl. CPC H01J 37/32357; H01J 37/321

(57) ABSTRACT

Aspects generally relate to methods and systems for advancing remote plasma technology by developing a resonant multi-reactor remote plasma source (RPS). The RPS system includes at least a first RPS and a second RPS, the first RPS contained within a boundary defined by the second RPS and a first set of spacers abutting the first RPS and a second set of spacers abutting the second RPS. The first RPS has a vertical configuration and the second RPS has a horizontal configuration. Both the first RPS and the second RPS have a rectangular shape. The first RPS has a first input port centrally disposed thereof and the second RPS has a second input port and a third input port disposed on opposed corners of the second RPS.

### BACKGROUND

### Field

Aspects generally relate to methods and systems for advancing remote plasma technology.

### Description of the Related Art

Remote plasma sources (RPSs) are a beneficial technology in various industrial and research applications. RPSs are used for generating plasma away from the primary processing area, allowing for precise control over the plasma characteristics and reducing contamination and damage to sensitive materials. RPSs create plasma in a location separate from the target material. The generated plasma is transported through a conduit to the processing chamber where the plasma interacts with the material. In semiconductor manufacturing, RPSs are used in processes like plasma-enhanced chemical vapor deposition (PECVD), plasma etching, and cleaning of semiconductor substrates. In previous RPS applications, radicals are typically fed into a chamber body from one plasma reactor, making center-to-edge profile control difficult to be achieved through source parameters. Moreover, the etch rate of RPSs is limited due to insufficient power-handling capabilities.

Therefore, there is a need for improved RPSs that enable better tunability and higher etch rate to achieve better center-to-edge profile control.

### SUMMARY

Aspects generally relate to methods and systems for advancing remote plasma technology by developing a resonant multi-reactor remote plasma source (RPS).

In one implementation, a remote plasma source (RPS) system includes at least a first RPS and a second RPS, the first RPS contained within a boundary defined by the second RPS and a first set of spacers abutting the first RPS and a second set of spacers abutting the second RPS.

In one implementation, a remote plasma source (RPS) system includes at least a first RPS and a second RPS, the first RPS disposed adjacent the second RPS such that the first RPS and the second RPS both have a vertical configuration and a first set of spacers abutting the first RPS and a second set of spacers abutting the second RPS.

In one implementation, a method includes arranging a first RPS having four pillars within a boundary defined by a second RPS having four pillars, the first RPS having a vertical configuration and the second RPS having a horizontal configuration, separating the pillars of the first RPS using a first set of spacers, separating the pillars of the second RPS using a second set of spacers, injecting first gases into a first input port of the first RPS, the first input port centrally disposed on a top portion of the first RPS, injecting second gases into a second input port and a third input port of the second RPS, the second input port and the third input port disposed on opposed corners of the second RPS, and producing radicals fed into a chamber body coupled to the first RPS and the second RPS.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of scope, as the disclosure may admit to other equally effective embodiments.

FIG. 1 is a perspective view of a resonant dual-reactor plasma source with one center input source and two edge input sources, according to one implementation.

FIG. 2A illustrates a front view of the resonant dual-reactor plasma source, according to one implementation.

FIG. 2B illustrates a top view of the resonant dual-reactor plasma source, according to one implementation.

FIGS. 3A-3D illustrate variations in electrical components on the resonant dual-reactor plasma source, according to one implementation.

FIG. 4A illustrates a front view of a resonant dual-reactor plasma source with two vertical reactors, according to one implementation.

FIGS. 5A-5F illustrate top views of different configurations for gas and radical inputs, according to one implementation.

FIGS. 6A-6F illustrate resonant dual-reactor plasma sources with different excitation methods, according to one implementation.

FIG. 7 is a flowchart of a method for implementing the resonant dual-reactor plasma source of FIG. 1, according to one implementation.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Aspects generally relate to methods and systems for advancing remote plasma technology by developing a resonant multi-reactor remote plasma source (RPS).

RPSs are valuable components in the semiconductor manufacturing industry, used to generate and control plasma separately from the processing chamber. This technology is instrumental in achieving precise and clean processing environments for advanced semiconductor device fabrication.

The main functions of RPSs include etching, deposition, resist removal, and surface cleaning. RPSs are used for etching processes where materials are selectively removed from the substrate. RPSs offer high etching rates with excellent uniformity, beneficial for producing intricate device architectures. In processes like chemical vapor deposition (CVD) and atomic layer deposition (ALD), RPSs can be used to enhance film growth, improve film properties, and reduce defect levels. RPSs further efficiently remove photoresist layers post-lithography with minimal damage to the underlying layers due to their ability to generate reactive species at lower temperatures. Moreover, RPSs are employed to clean substrate surfaces, removing organic and inorganic contaminants without causing damage to sensitive materials.

The advantages of RPSs include at least high purity processing, low damage, temperature control, and process flexibility. Since the plasma is generated remotely, contaminants from the plasma generation region do not enter the processing chamber, ensuring high-purity environments. The ability to control the energy of reactive species and minimize ion bombardment leads to less physical damage and lower defectivity in delicate structures. RPSs allow for low-temperature processing, which is beneficial for manufacturing advanced semiconductor devices, especially when working with temperature-sensitive materials. RPS systems offer a wide range of reactive species (e.g., radicals, ions) that can be tailored for specific applications, providing versatility in process development.

In CVD processes, radicals are highly reactive species that play a useful role in the deposition of thin films. These radicals are typically generated from precursor gases and are fed into the CVD processing chamber where they contribute to the formation of the desired material on the substrate. Radicals are atoms, molecules, or ions that have unpaired electrons. This makes them highly reactive and capable of initiating and sustaining chemical reactions. Radicals can be generated through various methods such as thermal decomposition, plasma excitation, photolysis (using light), or by chemical reactions. In a CVD process, common methods include thermal activation and plasma activation. Typical radicals include hydrogen radicals, oxygen radicals, and carbon radicals. Hydrogen radicals are often used in deposition of materials, oxygen radicals are used in processes involving oxides, and carbon radicals are used in deposition of carbon-based materials. Such radicals react with the substrate surface, providing the requisite chemical species that bond to the surface and form a thin film. Radicals enhance the deposition rate by providing a more reactive form of the precursor material and can improve the quality and uniformity of the film by facilitating more controlled and uniform reactions.

Gases are different than radicals. Gases are the initial precursor molecules introduced into the CVD chamber. They are typically in their stable molecular forms before undergoing any activation. Thus, gases are the primary source materials in the CVD process, whereas radicals serve as highly reactive intermediates that significantly enhance the efficiency, control, and quality of thin film deposition.

In typical RPS systems, the radicals are fed into a chamber body from one plasma reactor, making center-to-edge profile control difficult to be achieved through source parameters. Moreover, the etch rate of RPSs is limited due to insufficient power-handling capabilities. The etch rate in RPSs is influenced by a variety of factors, including energy losses during plasma transport, reactive species density, process control challenges, plasma chemistry, power limitations, material consideration, and operational conditions. Regarding power limitations, issues may arise relating to power transfer efficiency and power distribution. The efficiency of power transfer from the source to the plasma can be lower in remote setups, thus limiting the energy available to generate high-density plasma. Further, uniform distribution of power to generate consistent plasma can be more difficult to achieve, thus impacting the etch rate.

The example embodiments can alleviate the etch rate limitations of RPSs due to at least insufficient power-handling capabilities by providing for a resonant multi-reactor remote plasma source that enables better tunability and higher etch rate. The proposed RPS design includes a resonant, remote RPS that processes multiple reactors for center-to-edge profile control. Center-to-edge profile control refers to the ability to manage and maintain uniform plasma characteristics across the entire surface of a substrate during processing. Better uniformity leads to higher yield rates, thus reducing waste and increasing production efficiency. To provide for better center-to-edge profile control, the example embodiments present an RPS with nested plasma reactor chambers, where one plasma reactor chamber has a vertical configuration and one plasma reactor chamber has a horizontal configuration. Each plasma reactor includes rectangular metal pillars confined by four ceramic spacers. Inside these pillars are channels that allow gas to flow in and plasma/radicals to be generated. The width of the channel on the top portion is thinner than that on the other regions to enhance the plasma/radical generation on the bottom portion. The top and bottom ceramic spacers are used for electrical isolation, whereas two center spacers are designed for placing electrical components (e.g., capacitors, inductors, copper conductors, etc.).

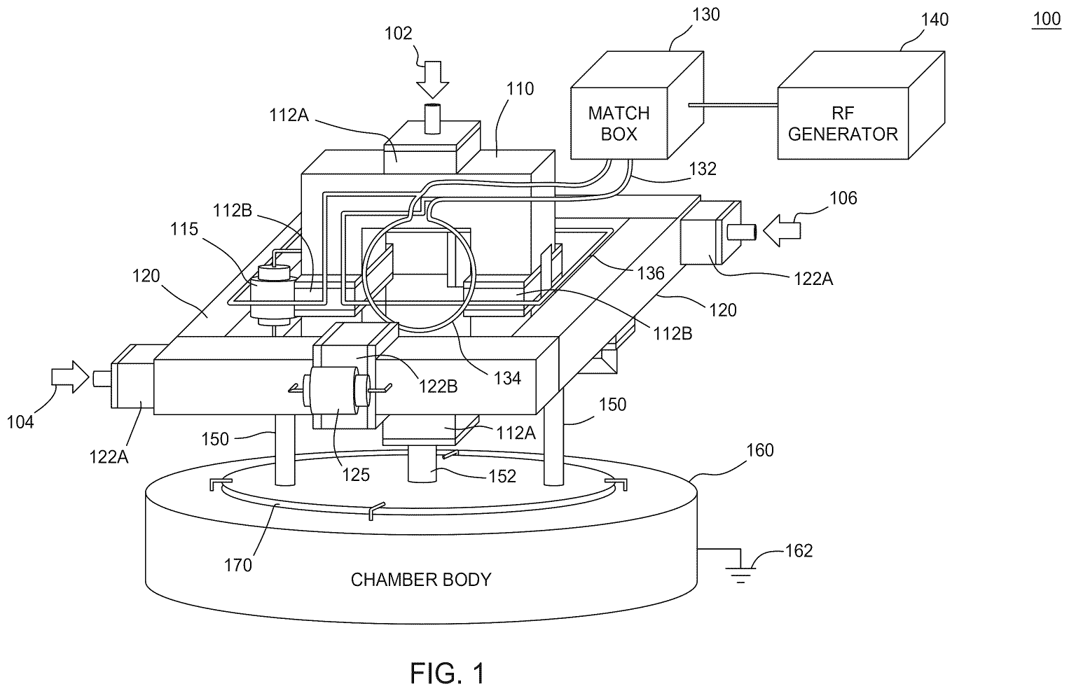

FIG. 1 is a perspective view of a resonant dual-reactor plasma source with one center input source and two edge input sources, according to one implementation.

The remote plasma source (RPS) system 100 includes a first RPS 110 and a second RPS 120. The first RPS 110 is positioned in a vertical configuration and the second RPS 120 is positioned in a horizontal configuration. The first RPS 110 is nested within the second RPS 120. Stated differently, the first RPS 110 is enclosed or contained or confined within the boundaries defined by the second RPS 120. The first RPS 110 may be disposed within an opening of the second RPS 120. The first RPS 110 may be referred to as an inner RPS and the second RPS 120 may be referred to as an outer RPS.

The first RPS 110 has a substantially square or rectangular shape. The second RPS 120 also has a substantially square or rectangular shape. The first RPS 110 and the second RPS 120 each include four pillars. Each of the four pillars includes a channel for receiving gases. The four pillars of the first RPS 110 and the second RPS 120 may be constructed from, e.g., metal. In one example, the metal is aluminum.

The first RPS 110 includes four spacers. A first spacer 112A may be formed on a top portion of the first RPS 110 and a second spacer 112A may be formed at a bottom portion of the first RPS 110. The first spacer 112A is centrally disposed on the top portion of the first RPS 110 and the second spacer 112A is centrally disposed on the bottom portion of the first RPS 110. A third spacer 112B may be formed on a left side portion of the first RPS 110 and a fourth spacer 112B may be formed on a right side portion of the first RPS 110. The third spacer 112B is centrally disposed on the left side portion of the first RPS 110 and the fourth spacer 112B is centrally disposed on the right side portion of the first RPS 110. The first and second spacers 112A and the third and fourth spacers 112B may be ceramic spacers. The first and second spacers 112A are used for electrical isolation, whereas the third and fourth spacers 112B are used for placing electrical components.

Similarly, the second RPS 120 includes four spacers. A first spacer 122A may be formed on a top portion of the second RPS 120 and a second spacer 122A may be formed at a bottom portion of the second RPS 120. The first spacer 122A is disposed on a top corner of the second RPS 120 and the second spacer 122A is disposed on a bottom corner of the second RPS 120. A third spacer 122B may be formed on a left side portion of the second RPS 120 and a fourth spacer 122B may be formed on a right side portion of the second RPS 120. The third spacer 122B is centrally disposed on the left side portion of the second RPS 120 and the fourth spacer 122B is centrally disposed on the right side portion of the second RPS 120. The first and second spacers 122A and the third and fourth spacers 122B may be ceramic spacers. The first and second spacers 122A are used for electrical isolation, whereas the third and fourth spacers 122B are used for placing electrical components.

The first and second spacers 112A and the third and fourth spacers 112B may abut or contact the first RPS 110 at one or more locations. The spacers may separate the four pillars of the first RPS 110. The spacers may also abut or contact an external surface of the first RPS 110. Similarly, the first and second spacers 122A and the third and fourth spacers 122B may abut or contact the second RPS 120 at one or more locations. The spacers may separate the four pillars of the second RPS 120. The spacers may also abut or contact an external surface of the second RPS 120.

The first RPS 110 has a first input 102 for receiving gases. The first input 102 is disposed on the top pillar of the first RPS 110, which is thinner or narrower than the other three pillars of the first RPS 110. The first input 102 is disposed adjacent the first spacer 112A.

The second RPS 120 has a second input 104 and a third input 106 for receiving gases. The second input 104 is disposed on a bottom portion of the second RPS 120 and the third input 106 is disposed on a top portion of the second RPS 120. The second input 104 is disposed on a corner of the bottom pillar of the second RPS 120 and the third input 106 is disposed on a corner of the top pillar of the second RPS 120. The second input 104 is diametrically opposed to the third input 106. Stated differently, the second input 104 is on an opposed end of the third input 106. The second input 104 and the third input 106 may be referred to as edge inputs.

In one example, the width of the pillars of the first RPS 110 may not be of equal width. For example, the width of the top pillar of the first RPS 110 may be thinner than the width of the other three pillars to enhance plasma/radical generation at the bottom pillar, which is adjacent to the chamber body 160. Similarly, the width of the pillars of the second RPS 120 may not be of equal width. For example, the width of the top pillar of the second RPS 120 may be thinner than the width of the other three pillars to enhance plasma/radical generation at the bottom pillar. The top pillar of the second RPS 120 may be the pillar configured to receive the third input 106.

In the RPS system 100, the first RPS 110 includes a first capacitor 115 adjacent to the third spacer 112B, whereas the second RPS 120 includes a second capacitor 125 adjacent the third spacer 122B. Thus, the first RPS 110 includes a first electrical component adjacent one of its four ceramic spacers and the second RPS 120 includes a second electrical components adjacent one of its four ceramic spacers. In other examples, other electrical components may be disposed adjacent the spacers, such as inductors. The electrical components are secured adjacent one or more spacers.

The first RPS 110 is excited by an exciter coil 132. The exciter coil 132 is powered by a radiofrequency (RF) generator 140 coupled to an impedance matching circuit 130. This configuration indicates an inductive coupling between the exciter coil 132 and the first RPS 110 or the generated plasma. If more than one exciter coil is used, such exciter coils may be powered together by one RF generator through one impedance matching circuit, or may be powered individually with multiple RF generators and impedance matching circuits. In one example, the exciter coil 132 may be constructed from copper. The exciter coil 132 extends around the first RPS 110 and adjacent a surface of the first RPS 110 such that a rectangular coil segment 136 and a circular coil segment 134 are formed.

The first RPS 110 and the second RPS 120 are coupled to the chamber body 160 including a ground connection 162 through a showerhead 170. A pair of connectors or rods or conduits 150 couple the second RPS 120 to the chamber body 160 through the showerhead 170 and a single connector or rod or conduit 152 couples the first RPS 110 to the chamber body 160 through the showerhead 170. The showerhead 170 prevents plasma from penetrating into the chamber body 160 and allows neutral gas and radicals to pass through. The chamber body 160 and the metal space above the showerhead 170 are electrically connected to prevent capacitive discharges within. Radicals generated by the vertical reactor flow into the chamber body 160 via a center of the first RPS 110 (i.e., the first input 102), while the second RPS 120 feeds radicals through edge openings (i.e., the second input 104 and the third input 106). This design helps improve radical etch uniformity and tunability.

Even though the RPS system 100 is shown having two RPSs, that is, a first RPS and a second RPS, it is understood that the RPS system 100 may include two or more RPSs in a variety of configurations. For example, the RPS system 100 may include 3 RPSs, where a first and a second RPS are nested within a third RPS. In another example, the RPS system 100 may include 4 RPSs, where a first, second, and third RPS are nested within a fourth RPS. In yet another example, the RPS system 100 may include 4 RPSs, where a first and second RPS are nested within a third and fourth RPS. Therefore, the RPS system 100 may include multiple RPSs disposed in a vertical configuration and multiple RPSs disposed in a horizontal configuration. As a result, the RPS system 100 may include a plurality of RPSs arranged in a plurality of different configurations based on desired application.

Moreover, each RPS of the RPS system 100 may be independently excited or energized. Thus, if the RPS system 100 includes a first RPS and a second RPS, the first RPS may be coupled to a first RF generator with respective impedance matching circuit and the second RPS may be coupled to a second RF generator with respective impedance matching circuit. If the RPS system 100 includes a first RPS, a second RPS, and a third RPS, the first RPS may be coupled to a first RF generator with respective impedance matching circuit, the second RPS may be coupled to a second RF generator with respective impedance matching circuit, and the third RPS may be coupled to a third RF generator with respective impedance matching circuit. As a result, each RPS of a multi-RPS system may be coupled to its own individual RF source and/or impedance matching circuit. Thus, each of the RPSs may be independently powered or energized.

Using two nested remote plasma sources can offer several advantages in terms of process control, uniformity, and efficiency. This configuration involving two plasma generation regions, one nested within the other, allows for more sophisticated plasma management. The advantages can relate to, e.g., enhanced uniformity, improved process tunability, increased plasma density, greater control over plasma chemistry, reduced contamination and damage, increased versatility and scalability, and enhanced process stability.

In particular, by having two RPSs, each generating plasma, it is possible to control the distribution of radicals more precisely across the substrate surface. The inner and outer sources can be tuned independently to ensure that reactive species are uniformly distributed from the center to the edge of the substrate. The outer source can compensate for the natural tendency of plasma density to drop off near the edges, leading to a more uniform etch or deposition profile. In some examples, each source can be controlled independently in terms of power, frequency, and gas flow, allowing for fine-tuning of plasma characteristics. This provides greater flexibility in optimizing the process for different materials and applications. Also, real-time adjustments can be made to one source without affecting the other, enabling dynamic control over the plasma environment. This is particularly useful for processes that involve precise control over etching or deposition rates. The combined effect of two plasma sources can increase the overall plasma volume, resulting in a higher concentration of reactive species. This can enhance the etching or deposition rates, improving process efficiency.

Moreover, by having two RPSs, in a nested configuration, different gases can be introduced into each plasma source, allowing for complex plasma chemistries that are not possible with a single source. This can be beneficial for processes that involve specific radical species or a combination of radicals for effective etching or deposition. The nested configuration can further allow for selective reactions to be promoted or suppressed by controlling the conditions in each source separately. By generating plasma in two separate but nested regions, contamination from the plasma sources can be minimized. This is particularly valuable for sensitive applications where impurities can affect the quality of the final product. The outer source can act as a buffer, controlling the energy of ions reaching the showerhead and thereby reducing the risk of damage. This is especially useful in processes where low-energy ions are preferred to prevent showerhead damage. Additionally, the nested configuration can be adapted for a wide range of applications, from semiconductor manufacturing to surface treatment and materials processing. The ability to fine-tune each plasma source independently makes this configuration highly versatile. This setup can be scaled up or down depending on the size of the substrate and the specific requirements of the process, offering flexibility in different manufacturing environments. Also, if one source experiences fluctuations or instability, the other source can help maintain overall process stability. This redundancy can lead to more consistent results and reduced downtime.

As a result, utilizing two or more nested remote plasma sources offers significant advantages in terms of uniformity, tunability, plasma density, control over plasma chemistry, contamination reduction, versatility, and process stability. This nested configuration allows for more precise and flexible control over plasma processes, leading to improved efficiency, quality, and consistency in various applications.

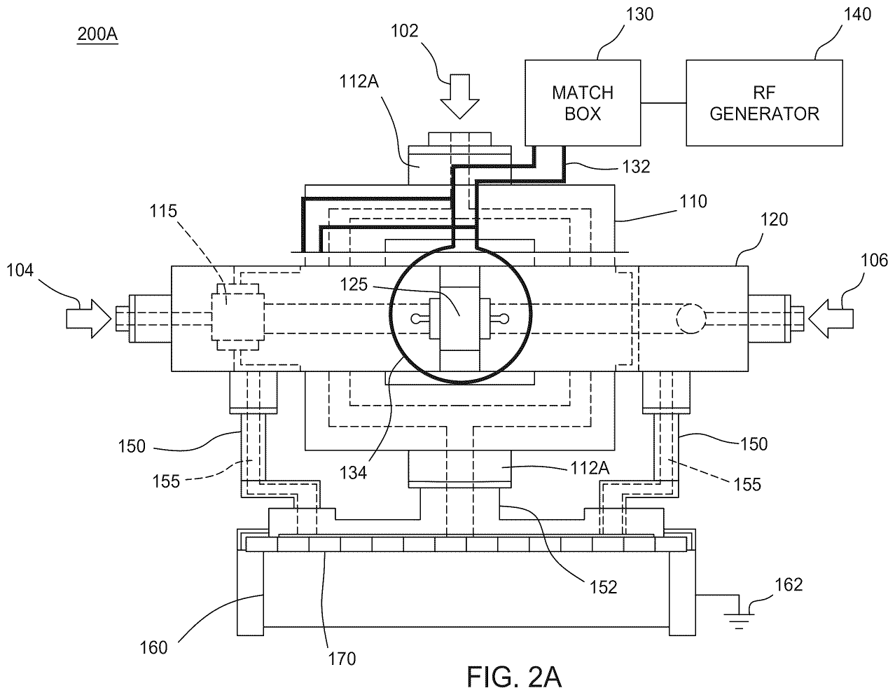

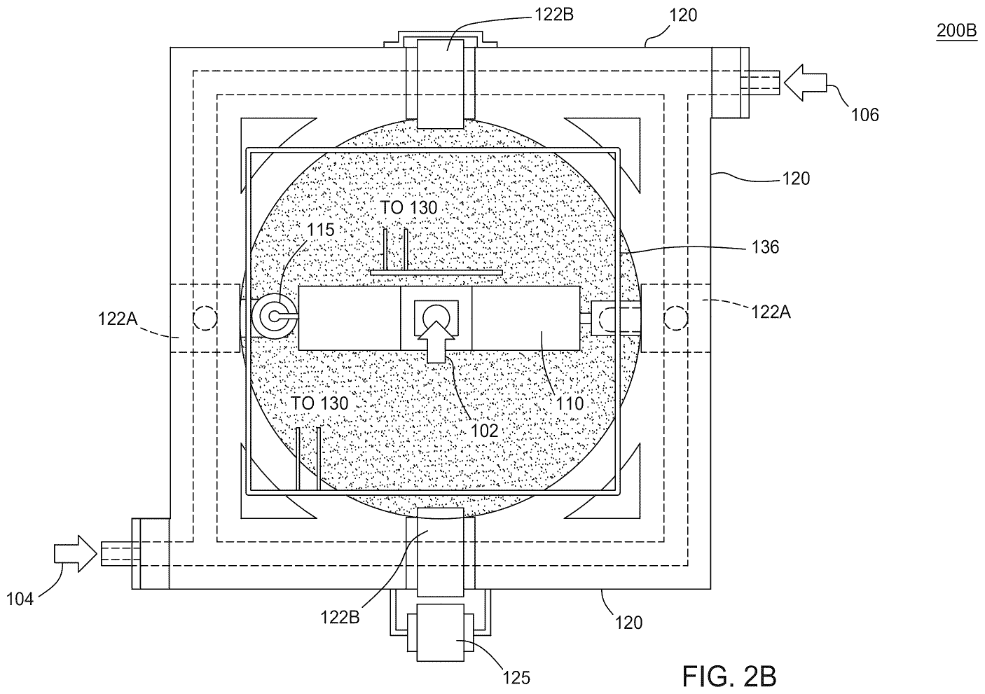

FIG. 2A illustrates a front view of the resonant dual-reactor plasma source, according to one implementation.

The front view 200A depicts the first RPS 110 and the second RPS 120, where the first RPS 110 is nested within the second RPS 120. The first RPS 110 includes the first input 102 for receiving gases and/or radicals and the second RPS 120 includes the second input 104 and the third input 106 for receiving gases and/or radicals. The gases are received by the first input 102, the second input 104, and the third input 106 and radicals 155 are generated, and provided to the chamber body 160. The radicals 155 are formed from the precursor gases when energy is supplied (i.e., the exciter coil 132 is activated by the RF generator 140).

The four spacers of the first RPS 110 are visible. The first spacer 112A is formed on a top portion of the first RPS 110 and the second spacer 112A is formed at a bottom portion of the first RPS 110. The first spacer 112A is centrally disposed on the top portion of the first RPS 110 and the second spacer 112A is centrally disposed on the bottom portion of the first RPS 110. The third spacer 112B is formed on a left side portion of the first RPS 110 and a fourth spacer 112B is formed on a right side portion of the first RPS 110. The third spacer 112B is centrally disposed on the left side portion of the first RPS 110 and the fourth spacer 112B is centrally disposed on the right side portion of the first RPS 110. The first capacitor 115 is placed adjacent to the third spacer 112B.

The first RPS 110 is connected to the chamber body 160 through the showerhead 170 by the single connector or rod or conduit 152 and the second RPS 120 is connected to the chamber body 160 through the showerhead 170 by the pair of connectors or rods or conduits 150. The exciter coil 132 is powered by the RF generator 140 coupled to the impedance matching circuit 130. The exciter coil 132 also includes the circular coil segment 134 formed on the front surface of the first RPS 110. The circular coil segment 134 is centrally disposed on the front surface of the first RPS 110. Stated differently, the circular coil segment 134 is disposed adjacent the opening of the front side of the first RPS 110.

FIG. 2B illustrates a top view of the resonant dual-reactor plasma source, according to one implementation.

The top view 200B depicts the first RPS 110 and the second RPS 120, where the first RPS 110 is nested or confined within the boundaries of the second RPS 120. The first RPS 110 is thus disposed within an opening of the second RPS 120. The first RPS 110 is thus disposed within the boundaries defined by the opening of the second RPS 120.

The four spacers of the second RPS 120 are visible. The first spacer 122A is formed on a top portion of the second RPS 120 and the second spacer 122A is formed at a bottom portion of the second RPS 120. The first spacer 122A is centrally disposed on the top portion of the second RPS 120 and the second spacer 122A is centrally disposed on the bottom portion of the second RPS 120. The third spacer 122B and the fourth spacer 122B are shown in relation to the first spacer 122A and the second spacer 122A. The third spacer 122B is centrally disposed on the pillar of the second RPS 120 and the fourth spacer 122B is centrally disposed on another pillar of the second RPS 120. The second capacitor 125 is placed adjacent to the third spacer 122B. The first capacitor 115 of the first RPS 110 is also shown. The electrical components are secured adjacent one or more spacers.

The top view 200B clearly shows the rectangular coil segment 136 of the exciter coil 132 which extends from the impedance matching circuit 130. The top view 200B also depicts the first input 102 for receiving gases, and the second input 104 and the third input 106 for receiving gases. The first input 102 is centrally disposed in the nested configuration. The second input 104 is placed at a first corner of the second RPS 120 and the third input 106 is placed at a second corner of the second RPS 120. The second input 104 is in an opposed relation relative to the third input 106. Stated differently, the second input 104 is in a diametrically opposed relationship with respect to the third input 106. The second input 104 and the third input 106 may be referred to as edge inputs.

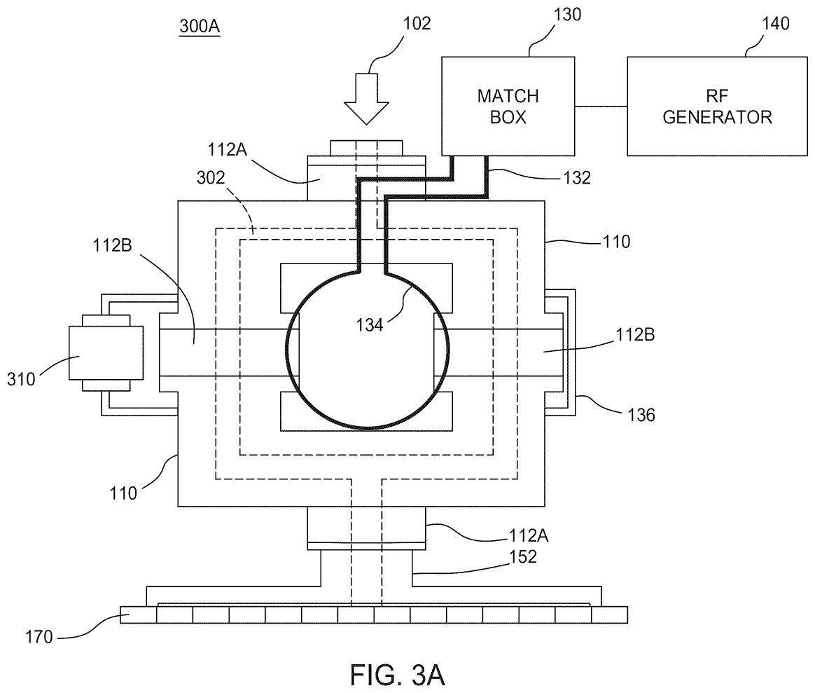

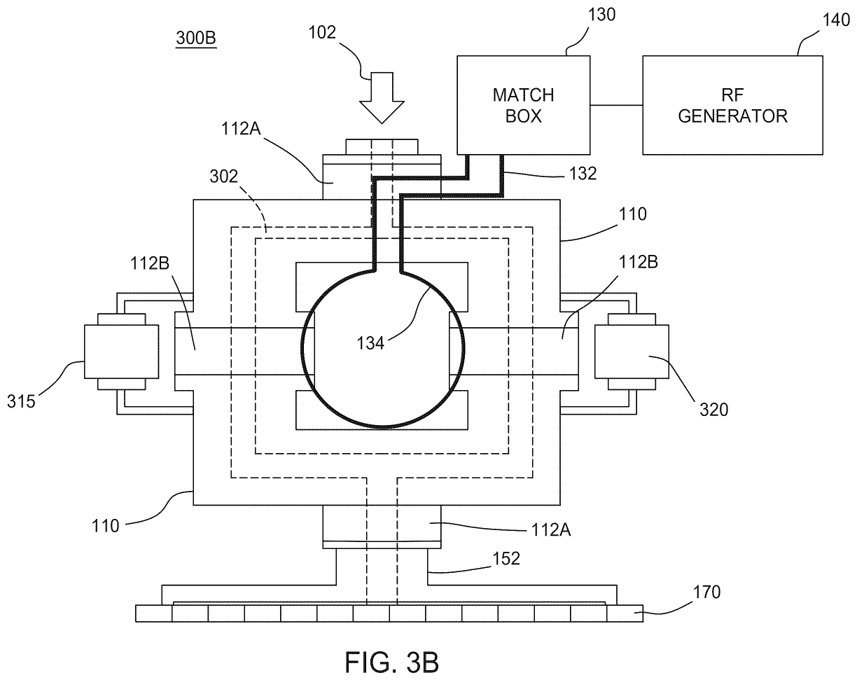

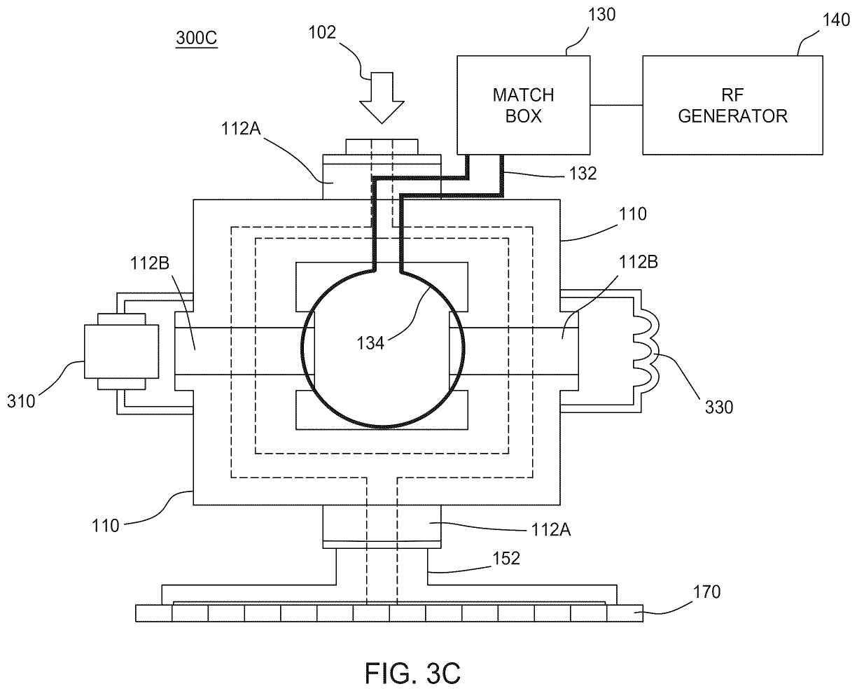

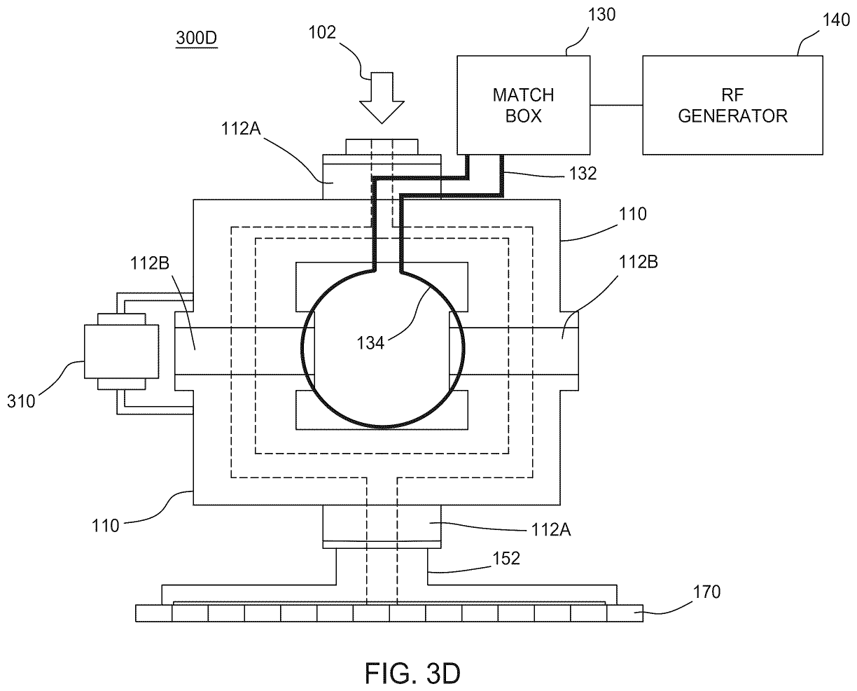

FIGS. 3A-3D illustrate variations in electrical components on the resonant dual-reactor plasma source, according to one implementation.

For sake of simplicity, only the first RPS 110 is illustrated. However, it is understood that such implementations are directed to a nested RPS having an inner RPS and an outer RPS. In other words, the first RPS 110 is positioned or placed or disposed within an opening defined by the second RPS 120.

FIG. 3A illustrates a front view 300A of the first RPS 110 where a single capacitor 310 is disposed adjacent a first spacer 112B and a single metal conductor 136 is disposed adjacent to a second spacer 112B. Thus, in one example, two electrical components are disposed adjacent to two spacers, those electrical components being a capacitor and a metal conductor.

FIG. 3B illustrates a front view 300B of the first RPS 110 where a first capacitor 315 is disposed adjacent the first spacer 112B and a second capacitor 320 is disposed adjacent a second spacer 112B. Thus, in another example, two electrical components are disposed adjacent to respective spacers, those electrical components both being capacitors.

FIG. 3C illustrates a front view 300C of the first RPS 110 where a capacitor 310 is disposed adjacent the first spacer 112B and an inductor 330 is disposed adjacent the second spacer 112B. Thus, in another example, two electrical components are disposed adjacent to respective spacers, those electrical components being a capacitor and an inductor.

FIG. 3D illustrates a front view 300D of the first RPS 110 where a single capacitor 310 is disposed adjacent a spacer 112B. Thus, in one example, one electrical component is disposed adjacent one spacer, that electrical component being a capacitor.

Regarding FIGS. 3A-3D, no matter what components are used, the resonant frequency of the system should be close to the RF driving frequency, so as to enable the maximum performance of the RPS system 100. Additionally, the top pillar of the first RPS 110 is thinner or narrower than the rest of the pillars of the first RPS 110. For example, the channel 302 in the top pillar is thinner or narrower than the rest of the pillars of the first RPS 110. In one example, the channel 302 may be half the width of the rest of the pillars of the first RPS 110. In another example, the channel 302 may be 10-30% the width of the rest of the pillars of the first RPS 110. The width of the channel on the top portion is thinner than that on the other regions to enhance the plasma/radical generation on the bottom portion.

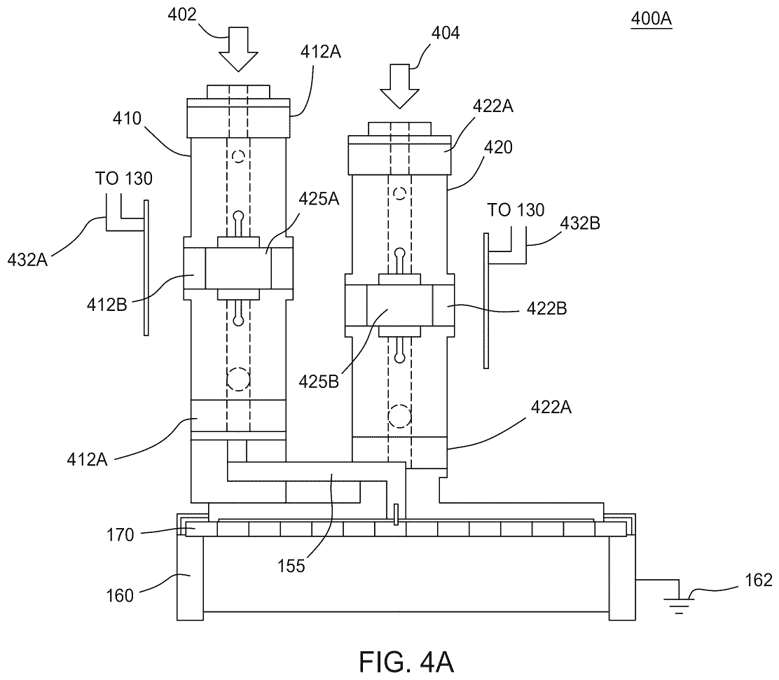

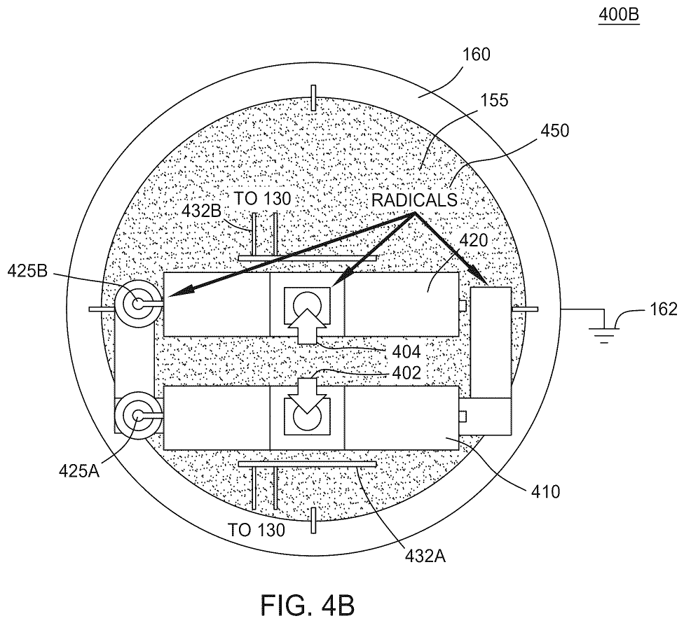

FIG. 4A illustrates a front view 400A of a resonant dual-reactor plasma source with two vertical reactors, according to one implementation.

In another embodiment, the RPS system may include a first RPS 410 and a second RPS 420, where the first RPS 410 is in a vertical configuration and the second RPS 420 is in a vertical configuration. In other words, the first RPS 410 is parallel to the second RPS 420. This configuration also provides for a high etch rate and superior center-to-edge etch profile control.

A side view of the first RPS 410 is shown where a first input 402 supplies gases to the first RPS 410. The first RPS 410 includes four spacers, however, one spacer 412B is visible in the side view. The spacer 412B has a first capacitor 425A disposed adjacent to it. As such, the spacer 412B is a spacer designed to be placed adjacent electrical components. Also, the top and bottom spacers 412A are visible in the side view. An impedance matching circuit 130 may be coupled to the first RPS 410 via an exciter coil 432A. The gases are processed to generate the radicals 155 that are fed into the chamber body 160 through the showerhead 170. The chamber body 160 also includes the ground connection 162.

Similarly, a side view of the second RPS 420 is shown where a second input 404 supplies gases to the second RPS 420. The second RPS 420 includes four spacers, however, one spacer 422B is visible in the side view. The spacer 422B has a second capacitor 425B disposed adjacent to it. As such, the spacer 422B is a spacer designed to be placed adjacent electrical components. Also, the top and bottom spacers 422A are visible in the side view. An impedance matching circuit 130 may be coupled to the second RPS 420 via an exciter coil 432B. The gases are processed to generate the radicals 155 that are fed into the chamber body 160 through the showerhead 170.

Therefore, in FIG. 4A two RPSs are provided, where the RPSs are vertical with respect to the chamber body 160. In another example, a plurality of RPSs may be disposed vertically over the chamber body 160. The RPS system of FIG. 4A may include, e.g., 3 RPSs, 4 RPSs, 5 RPSs, 10 RPSs, 12 RPSs etc. A series of multiple vertical RPSs may be formed to provide the radicals 155 to the chamber body 160.

FIG. 4B illustrates a top view 400B of resonant dual-reactor plasma source with two vertical reactors, according to one implementation.

The top pillar of the first RPS 410 and the top pillar of the second RPS 420 are depicted. The first RPS 410 is parallel to the second RPS 420. The first RPS 410 has the first input 402 and the second RPS 420 has the second input 404. The radicals 155 may be inserted into the first RPS 410 and the second RPS 420. The radicals 155 are fed into the chamber body 160 through the showerhead 170. The first capacitor 425A of the first RPS 410 and the second capacitor 425B of the second RPS 420 are visible and are disposed adjacent to each other. The exciter coils 432A and 432B are powered by the RF generator 140 coupled to the impedance matching circuit 130. The exciter coil 432A may be powered by a first RF generator and the exciter coil 432B may be powered by a second RF generator. Thus, each RPS may be independently powered or energized.

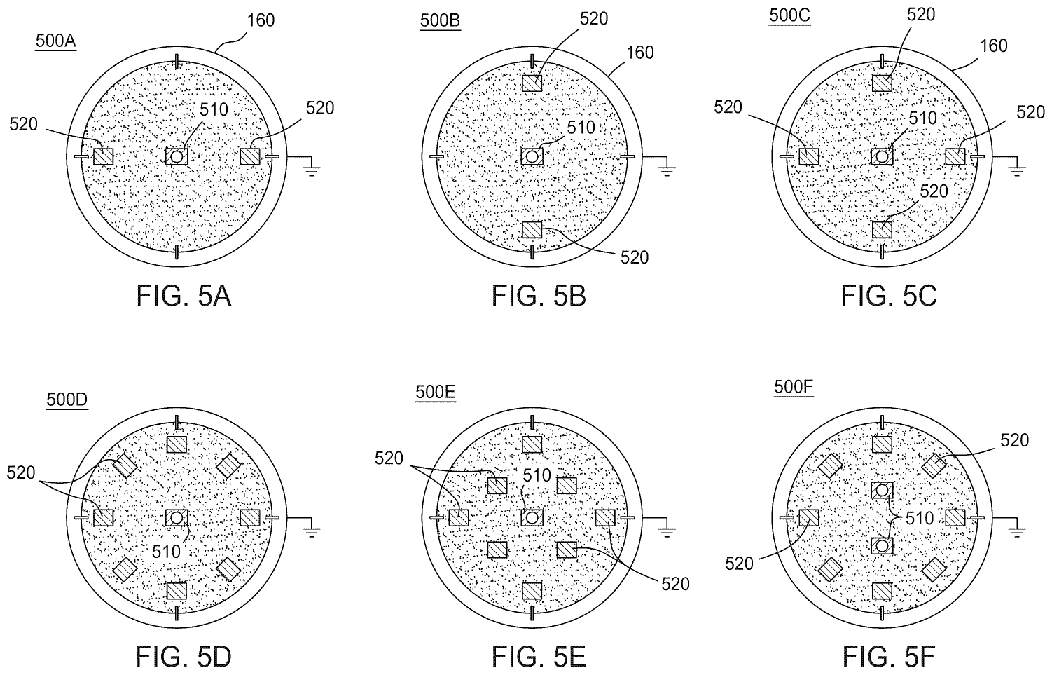

FIGS. 5A-5F illustrate top views of different configurations for gas and radical inputs, according to one implementation.

FIG. 5A illustrates a top view 500A of a first configuration of input ports. A first input 510 receives gases and injects radicals into the bottom chamber 160 at the same location. A second set of inputs 520 injects radicals into the bottom chamber 160. The first input 510 may be aligned with the second set of inputs 520. The first input 510 may be centrally disposed. The second set of inputs 520 may be disposed on opposed ends of the first input 510. The second set of inputs 520 may be disposed over the edges of chamber body 160. The second set of inputs 520 may be disposed horizontally.

FIG. 5B illustrates a top view 500B of a second configuration of input ports. A first input 510 receives gases and injects radicals into the bottom chamber 160. A second set of inputs 520 injects radicals into the bottom chamber 160. The first input 510 may be aligned with the second set of inputs 520. The first input 510 may be centrally disposed. The second set of inputs 520 may be disposed on opposed ends of the first input 510. The second set of inputs 520 may be disposed over the edges of chamber body 160. The second set of inputs 520 may be disposed vertically.

FIG. 5C illustrates a top view 500C of a third configuration of input ports. A first input 510 receives gases and injects radicals. A second and third set of inputs 520 injects radicals into the bottom chamber 160. The first input 510 may be aligned with the second and third set of inputs 520. The first input 510 may be centrally disposed. The second set of inputs 520 may be disposed on opposed ends of the first input 510. The third set of inputs 520 may be disposed on opposed ends of the first input 510. The second and third set of inputs 520 may be disposed over the edges of chamber body 160. The second set of inputs 520 may be disposed horizontally and the third set of inputs may be vertical. The first input 510 and the second set of inputs 520 form a cross configuration.

FIG. 5D illustrates a top view 500D of a fourth configuration of input ports. A first input 510 receives gases injects radicals into the bottom chamber 160, and is centrally disposed. A second set of inputs 520 are circumferentially placed around the edge. In the example, the second set of inputs 520 include 6 inputs. However, any number of inputs may be provided. The second set of inputs 520 form a circular configuration.

FIG. 5E illustrates a top view 500E of a fifth configuration of input ports. A first input 510 receives gases injects radicals into the bottom chamber 160, and is centrally disposed. A second set of inputs 520 surrounds the first input 510. The example, the second set of inputs 520 include 8 inputs. However, any number of inputs may be provided. The second set of inputs 520 form a rectangular configuration.

FIG. 5F illustrates a top view 500F of a sixth configuration of input ports. A first input 510 includes a set of inputs to receive gases injects radicals. The set of first inputs 510 are centrally disposed. A second set of inputs 520 are circumferentially placed around the edge. In the example, the second set of inputs 520 include 8 inputs. However, any number of inputs may be provided. The second set of inputs 520 form a circular configuration.

Any number of different input configurations may be contemplated forming any number of different geometric designs. The geometric configuration of input ports in RPSs can influence the distribution and uniformity of the plasma across the substrate. By strategically placing the input ports, engineers can better control the center-to-edge profile and ensure uniform treatment of the substrate. Other input configurations can include axial configurations, radial configurations, annular configurations, showerhead configurations, etc. Each configuration offers unique advantages. The choice of configuration depends on the specific requirements of the process, such as substrate size, desired uniformity, and the type of plasma treatment.

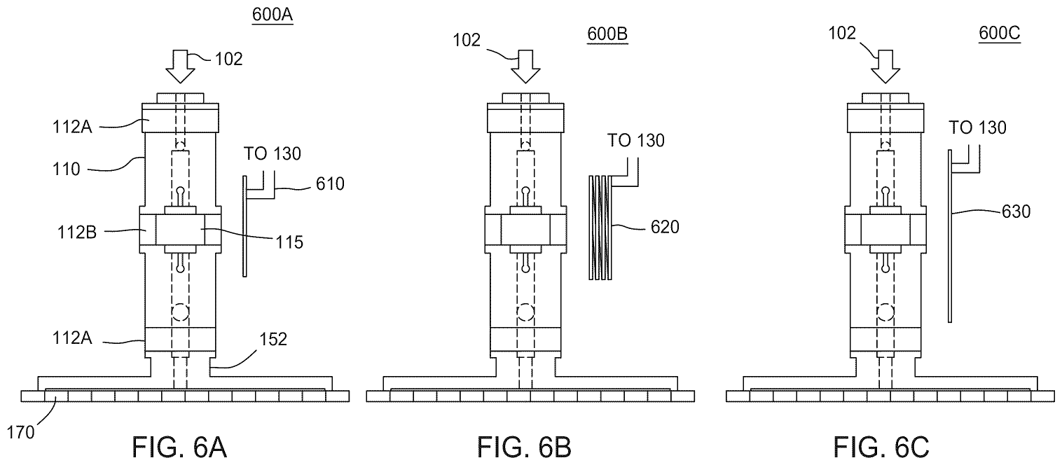

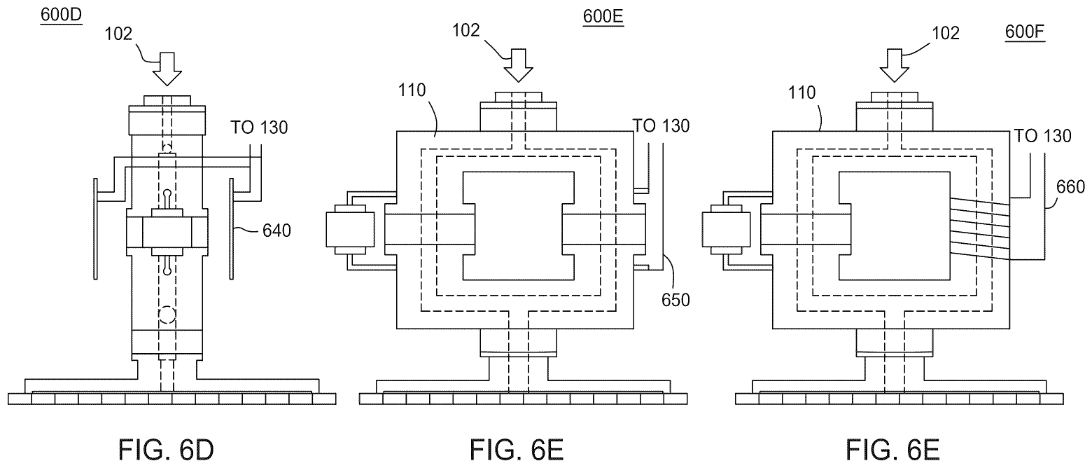

FIGS. 6A-6F illustrate resonant dual-reactor plasma sources with different excitation methods, according to one implementation.

The exciter coil of RPSs is responsible for generating the electromagnetic fields that ionize gas to create the plasma. The performance and the characteristics of the plasma depend on the design of the exciter coil, including the number of turns, size, and the number of coils.

FIG. 6A illustrates a side view 600A of the first RPS 110. The front view 600A depicts the exciter coil 610 having a single turn.

FIG. 6B illustrates a side view 600B of the first RPS 110. The front view 600B depicts the exciter coil 620 having multiple turns.

FIG. 6C illustrates a side view 600C of the first RPS 110. The front view 600C depicts the exciter coil 630 having a different size than the exciter coil 610 of FIG. 6A and the exciter coil 620 of FIG. 6B. The exciter coil 630 may be twice the length of the exciter coil 610 of FIG. 6A and the exciter coil 620 of FIG. 6B.

FIG. 6D illustrates a side view 600D of the first RPS 110. The front view 600D depicts two exciter coils 640 each having a single turn. Therefore, multiple exciter coils may be employed.

FIG. 6E illustrates a front view 600E of the first RPS 110. The front view 600E depicts the exciter coil 650 directly coupled to the first RPS 110 to ionize the gases and generate radicals.

FIG. 6F illustrates a front view 600F of the first RPS 110. The front view 600F depicts the exciter coil 660 directly coupled to the first RPS 110 in a transformer-like configuration.

Regarding FIGS. 6A-6F, the number of turns refers to how many times the coil wire loops around the core. More turns increases the inductance of the coil, which can enhance the magnetic field strength and improve plasma density. A higher number of turns may allow for better power handling and more efficient energy transfer. More turns also increases the resistance of the coil, which may lead to higher energy losses. As such, a balance between inductance and resistance should be optimized for efficient plasma generation. The size of the coil includes its diameter, length, and overall volume. Larger coils can produce a more uniform magnetic field over a larger area, which is beneficial for uniform plasma generation. The physical size of the coil affects the resonant frequency of the coil, impacting the efficiency of power transfer at different frequencies. However, use of larger coils may involve more sophisticated cooling mechanisms to manage heat dissipation. As a result, the coil size should be matched to the chamber size and the desired plasma volume. The number of coils refers to whether a single coil or multiple coils are used in the plasma source. Multiple coils can offer better control over the magnetic field distribution and plasma characteristics. Using multiple coils may allow for zonal control, thus enabling more precise tuning of plasma density and uniformity across the substrate. Therefore, each parameter affects the magnetic field strength, plasma density, uniformity, and overall system performance. Optimizing the coil characteristics is beneficial in meeting the specific requirements of various plasma processing applications.

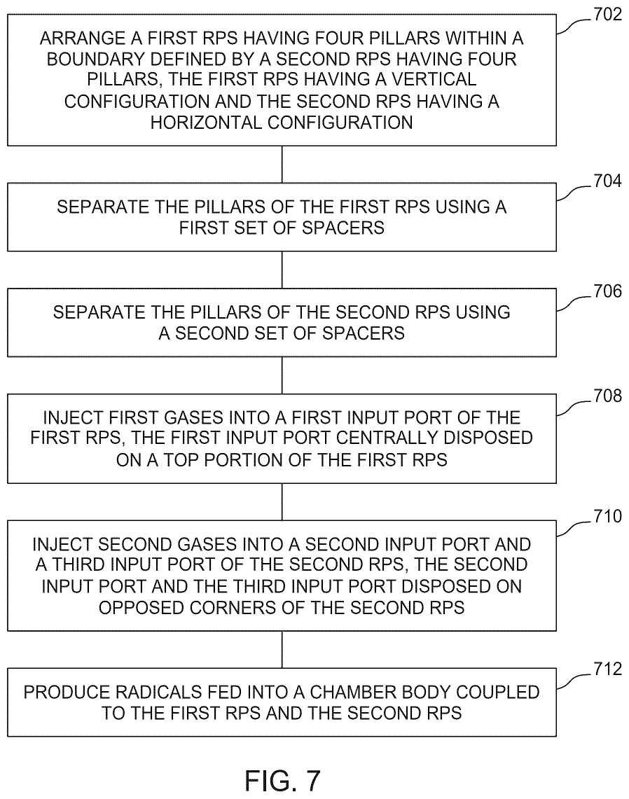

FIG. 7 is a flowchart of a method for implementing the resonant dual-reactor plasma source of FIG. 1, according to one implementation.

At block 702, arrange a first RPS having four pillars within a boundary defined by a second RPS having four pillars, the first RPS having a vertical configuration and the second RPS having a horizontal configuration.

At block 704, separate the pillars of the first RPS using a first set of spacers.

At block 706, separate the pillars of the second RPS using a second set of spacers.

At block 708, inject first gases into a first input port of the first RPS, the first input port centrally disposed on a top portion of the first RPS.

At block 710, inject second gases into a second input port and a third input port of the second RPS, the second input port and the third input port disposed on opposed corners of the second RPS.

At block 712, produce radicals fed into a chamber body coupled to the first RPS and the second RPS.

In conclusion, the example embodiments allow for advancing remote plasma technology by developing a resonant multi-reactor RPS or multi-reactor RPS system. The RPS system includes a first RPS and a second RPS. The first RPS is nested or contained or confined within the second RPS to provide for better center-to-edge profile control. The example embodiments present an RPS with nested plasma reactor chambers, where one plasma reactor chamber has a vertical configuration and one plasma reactor chamber has a horizontal configuration. Each plasma reactor includes rectangular metal pillars confined by four ceramic spacers. Inside these pillars are channels that allow gas to flow in and plasma/radicals to generate. The width of the channel on the top portion is thinner than that on the other regions to enhance the plasma/radical generation on the bottom portion. The top and bottom ceramic spacers are used for electrical isolation, whereas two center spacers are designed for placing electrical components (e.g., capacitors, inductors, copper conductors, etc.). Using two nested remote plasma sources can offer several advantages in terms of process control, uniformity, and efficiency. This configuration involving two plasma generation regions, one nested within the other, allows for more sophisticated plasma management. The advantages can relate to, e.g., enhanced uniformity, improved process tunability, increased plasma density, greater control over plasma chemistry, reduced contamination and damage, increased versatility and scalability, and enhanced process stability.

While this specification contains many specific implementation details, these should not be construed as limitations on the scope of what may be claimed, but rather as descriptions of features that may be specific to particular implementations. Certain features that are described in this specification in the context of separate implementations may also be implemented, in combination, in a single implementation. Conversely, various features that are described in the context of a single implementation may also be implemented in multiple implementations, separately, or in any suitable sub-combination. Moreover, although previously described features may be described as acting in certain combinations and even initially claimed as such, one or more features from a claimed combination may, in some cases, be excised from the combination, and the claimed combination may be directed to a sub-combination or variation of a sub-combination.

Particular implementations of the subject matter have been described. Other implementations, alterations, and permutations of the described implementations are within the scope of the following claims as will be apparent to those skilled in the art. While operations are depicted in the drawings or claims in a particular order, this should not be understood as requiring that such operations be performed in the particular order shown or in sequential order, or that all illustrated operations be performed (some operations may be considered optional) to achieve desirable results. In certain circumstances, multitasking or parallel processing (or a combination of multitasking and parallel processing) may be advantageous and performed as deemed appropriate. While the various steps in an embodiment method or process are presented and described sequentially, one of ordinary skill in the art will appreciate that some or all of the steps may be executed in different order, may be combined, or omitted, and some or all of the steps may be executed in parallel. The steps may be performed actively or passively. The method or process may be repeated or expanded to support multiple components or multiple users within a field environment. Accordingly, the scope should not be considered limited to the specific arrangement of steps shown in a flowchart or diagram.

Furthermore, any claimed implementation is considered to be applicable to at least a computer-implemented method; a non-transitory, computer-readable medium storing computer-readable instructions to perform the computer-implemented method; and a computer system including a computer memory interoperability coupled with a hardware processor configured to perform the computer-implemented method or the instructions stored on the non-transitory, computer-readable medium.

As used herein, “a CPU”“, controller”, “a processor”, “at least one processor”, or “one or more processors”, generally refers to a single processor configured to perform one or multiple operations or multiple processors configured to collectively perform one or more operations. In the case of multiple processors, the one or more operations could be divided amongst different processors, though one processor may perform multiple operations, and multiple processors could collectively perform a single operation. Similarly, “a memory”“, at least one memory”, or “one or more memories”, generally refers to a single memory configured to store data and/or instructions, multiple memories configured to collectively store data and/or instructions.

As used herein, “gas” and “fluid” may be used interchangeable with either term generally referring to elements, compounds, materials, etc., having the properties of a gas, a fluid, or both a gas and a fluid.

Unless defined otherwise, all technical and scientific terms used have the same meaning as commonly understood by one of ordinary skill in the art to which these systems, apparatuses, methods, processes and compositions belong.

In this disclosure, the terms “top”, “bottom”, “side”, “above”, “below”, “up”, “down”, “upward”, “downward,” “horizontal,” “vertical,” and the like do not refer to absolute directions. Instead, these terms refer to directions relative to a nonspecific plane of reference. This non-specific plane of reference may be vertical, horizontal, or other angular orientation.

The singular forms “a”, “an”, and “the”, include plural referents, unless the context clearly dictates otherwise. Within a claim, reference to an element in the singular is not intended to mean “one and only one” unless specifically so stated, but rather “one or more”. Unless specifically stated otherwise, the term “some” refers to one or more.

Embodiments of the present disclosure may suitably “comprise”, “consist”, or “consist essentially of”, the limiting features disclosed, and may be practiced in the absence of a limiting feature not disclosed. As used here and in the appended claims, the words “comprise”, “has”, and “include”, and all grammatical variations thereof are each intended to have an open, non-limiting meaning that does not exclude additional elements or steps.

“Optional” and “optionally” means that the subsequently described material, event, or circumstance may or may not be present or occur. The description includes instances where the material, event, or circumstance occurs and instances where it does not occur.

“Coupled” and “coupling” means that the subsequently described material is connected to previously described material. The connection may be a direct, or indirect connection, and may, or may not, include intermediary components such as plumbing, wiring, fasteners, mechanical power transmission, electrical communication, wired and/or wireless transmission, etc., which may be suitable to affect operation of the components.

As used, the term “determining” encompasses a wide variety of actions. For example, “determining” may include calculating, computing, processing, deriving, investigating, looking up, for example, looking up in a table, a database, or another data structure, and ascertaining. In addition, “determining” may include receiving, for example, receiving information, and accessing, for example, accessing data in a memory. In addition, “determining”may include resolving, selecting, choosing, and establishing.

When the word “approximately” or “about” are used, this term may mean that there may be a variance in value of up to ±10%, of up to 5%, of up to 2%, of up to 1%, of up to 0.5%, of up to 0.1%, or up to 0.01%.

Ranges may be expressed as from about one particular value to about another particular value, inclusive. When such a range is expressed, it is to be understood that another embodiment is from the one particular value to the other particular value, along with all particular values and combinations thereof within the range.

As used, terms such as “first” and “second” are arbitrarily assigned and are merely intended to differentiate between two or more components of a system, an apparatus, or a composition. It is to be understood that the words “first” and “second” serve no other purpose and are not part of the name or description of the component, nor do they necessarily define a relative location or position of the component. Furthermore, it is to be understood that that the mere use of the term “first” and “second” does not require that there be any “third” component, although that possibility is envisioned under the scope of the various embodiments described.

Although only a few example embodiments have been described in detail, those skilled in the art will readily appreciate that many modifications are possible in the example embodiments without materially departing from the disclosed scope as described. Accordingly, all such modifications are intended to be included within the scope of this disclosure as defined in the following claims. In the claims, means-plus-function clauses are intended to cover the structures described as performing the recited function and not only structural equivalents, but also equivalent structures. It is the express intention of the applicant not to invoke 35 U.S. C. § 112(f), for any limitations of any of the claims, except for those in which the claim expressly uses the words ‘means for’ together with an associated function.

While the foregoing is directed to embodiments of the present disclosure, other and further embodiments of the disclosure may be devised without departing from the basic scope thereof, and the scope thereof is determined by the claims that follow.

What is claimed is:

1. A remote plasma source (RPS) system, comprising:
at least a first RPS and a second RPS, the first RPS contained within a boundary defined by the second RPS; and
a first set of spacers abutting the first RPS and a second set of spacers abutting the second RPS.

2. The RPS system of claim 1, wherein the first RPS has a vertical configuration and the second RPS has a horizontal configuration.

3. The RPS system of claim 1, wherein the first RPS has a first rectangular shape and the second RPS has a second rectangular shape.

4. The RPS system of claim 1, wherein the first RPS has four pillars separated from each other by the first set of spacers and wherein the second RPS has four pillars separated from each other by the second set of spacers.

5. The RPS system of claim 4, wherein each of the four pillars of the first RPS includes a channel and one channel of the four pillars has a width that is narrower than widths of the other channels.

6. The RPS system of claim 1, wherein the first RPS has a first input port and the second RPS has a second input port and a third input port.

7. The RPS system of claim 6, wherein the first input port is centrally disposed on a top portion of the first RPS.

8. The RPS system of claim 6, wherein the second input port and the third input port are disposed on opposed corners of the second RPS.

9. The RPS system of claim 1, wherein the first RPS and the second RPS include a plurality of first inputs and a plurality of second inputs arranged in a number of different geometric configurations.

10. The RPS system of claim 1,
wherein at least two spacers of the first set of spacers of the first RPS provide electrical isolation and at least one spacer of the first set of spacers of the first RPS secures a first electrical component thereto; and
wherein at least two spacers of the second set of spacers of the second RPS provide electrical isolation and at least one spacer of the second set of spacers of the second RPS secures a second electrical component thereto.

11. The RPS system of claim 1, wherein the first RPS and the second RPS are energized by a common excited coil powered by a radiofrequency (RF) generator.

12. The RPS system of claim 1, wherein the first RPS and the second RPS are independently energized by different excited coils powered by different RF generators.

13. A remote plasma source (RPS) system, comprising:
at least a first RPS and a second RPS, the first RPS disposed adjacent the second RPS such that the first RPS and the second RPS both have a vertical configuration; and
a first set of spacers abutting the first RPS and a second set of spacers abutting the second RPS.

14. The RPS system of claim 13, wherein the first RPS has a first rectangular shape and the second RPS has a second rectangular shape.

15. The RPS system of claim 13, wherein the first RPS has four pillars separated from each other by the first set of spacers and wherein the second RPS has four pillars separated from each other by the second set of spacers.

16. The RPS system of claim 15, wherein each of the four pillars of the first RPS includes a channel and one channel of the four pillars has a width that is narrower than widths of the other channels.

17. The RPS system of claim 15, wherein the first RPS has a first input port centrally disposed on a top portion of the first RPS and the second RPS has a second input port centrally disposed on a top portion of the second RPS.

18. The RPS system of claim 15,
wherein at least two spacers of the first set of spacers of the first RPS provide electrical isolation and at least one spacer of the first set of spacers of the first RPS secures a first electrical component thereto; and
wherein at least two spacers of the second set of spacers of the second RPS provide electrical isolation and at least one spacer of the second set of spacers of the second RPS secures a second electrical component thereto.

19. The RPS system of claim 15, wherein the first RPS and the second RPS are independently energized by different excited coils powered by different RF generators.

20. A method, comprising:
arranging a first RPS having four pillars within a boundary defined by a second RPS having four pillars, the first RPS having a vertical configuration and the second RPS having a horizontal configuration;
separating the pillars of the first RPS using a first set of spacers;
separating the pillars of the second RPS using a second set of spacers;
injecting first gases into a first input port of the first RPS, the first input port centrally disposed on a top portion of the first RPS;
injecting second gases into a second input port and a third input port of the second RPS, the second input port and the third input port disposed on opposed corners of the second RPS; and
producing radicals fed into a chamber body coupled to the first RPS and the second RPS.
